(19) United States
(12) Patent Application Publication
(10) Pub. No.: US 2026/0236343 A1
(43) Pub. Date: Aug. 13, 2026

(54) CORRELATED MULTI-CODEWORD ERROR CORRECTION CODING

(71) Applicant: Rambus Inc., San Jose, CA (US)

(72) Inventor: Michael Alexander Hamburg, Rosmalen (NL)

(21) Appl. No.: 19/157,212

(22) PCT Filed: Feb. 20, 2024
(86) PCT No.: PCT/US2024/016548

§ 371 Date: Aug. 15, 2025

Related U.S. Application Data
(60) Provisional application No. 63/486,308, filed on Feb. 22, 2023.

(51) Int. Cl. G06F 11/10

(52) U.S. Cl. CPC G06F 11/1004

(57) ABSTRACT

Aspects and implementations include systems and techniques for efficient detection and correction of errors in stored and communicated data. On encoding, data is partitioned into multiple portions of data symbols and corresponding codewords having one or more error correction (EC) symbols are generated. A mixing transformation is then applied to obtain mixed codewords. On decoding, an unmixing transformation is applied to the mixed codewords before one or more EC codes are applied to identify locations of error(s) in the plurality of codewords. Responsive to determining whether a number of the locations of error(s) is above a threshold number, an EC decoder determines if decoding has been successful or declares an uncorrectable decoding error.

### CLAIM OF PRIORITY

This application is a National Stage of International Application No. PCT/US24/16548, filed Feb. 20, 2024, which claims the benefit under 35 U.S.C. § 119(e) of U.S. Provisional Patent Application No. 63/486,308 filed Feb. 22, 2023, both of which are incorporated by reference herein.

### TECHNICAL FIELD

The disclosure pertains to computing applications, more specifically to systems and techniques that improve reliability of recovering data that may be corrupted during data storage, retrieval, and communication, using error correction data.

### BRIEF DESCRIPTION OF THE DRAWINGS

The present disclosure will be understood more fully from the detailed description given below and from the accompanying drawings of various implementations of the disclosure.

FIG. 1 is a block diagram of an example computer system in which implementations of the disclosure may operate.

FIGS. 2A-C illustrate example operations of codeword mixing for reduction of miscorrection occurrences in application of error correction codes, in accordance with some aspects of the present disclosure.

FIG. 3A illustrates example operations of codeword mixing for reduction of miscorrection occurrences in application of error correction codes with systematic storage of data, in accordance with some aspects of the present disclosure.

FIG. 3B illustrates example operations of codeword mixing with systematic storage of data and a reduced computational load, in accordance with some aspects of the present disclosure

FIG. 4 illustrates example operations of codeword mixing that emulates a stronger code, in accordance with some aspects of the present disclosure.

FIG. 5 illustrates example operations of codeword mixing using collaborative decoding, in accordance with some aspects of the present disclosure.

FIG. 6 is a flow diagram illustrating an example method of codeword mixing during error correction encoding for reduction of miscorrection occurrences, in accordance with some implementations of the present disclosure.

FIG. 7 is a flow diagram illustrating an example method of codeword unmixing during error correction decoding for reduction of miscorrection occurrences, in accordance with some implementations of the present disclosure.

FIG. 8 depicts a block diagram of an example computer system operating in accordance with one or more aspects of the present disclosure.

### DETAILED DESCRIPTION

Aspects and implementations of the present disclosure are related to systems and techniques that detect and correct failure of data storage and communication operations. Error correction (EC) techniques operate by storing data in conjunction with additional EC data (e.g., EC codes or parity symbols) that is redundant under ideal conditions but enables identifying parts of data that are lost in transmission or corrupted during write operations, storing of the data, or retrieval of the data. In one non-limiting illustrative example, 32 symbols (e.g., bytes, double-bytes, etc.) of data may be stored in a memory device (or communicated over a network) together with 8 EC symbols generated for the data according to a particular EC code. In some secure memory systems, 40 symbols of a codeword (that includes both data symbols and EC symbols) may be spread over multiple memory chips, so that a failure of any one chip does not result in irreversible loss of the data. For example, 10 chips may be used to store 32 symbols, with 8 chips storing 4 symbols of data each, and 2 additional chips storing 4 EC symbols each. For the speed of memory write and read operations, each chip may be accessed using multiple buses (channels), e.g., 4 or 2 channels per chip, so that each symbol (or a pair of symbols) is stored and accessed in a respective chip via a separate channel. Such multi-chip memory systems enable reliable, secure, and fast (parallelized) memory accesses provided that the units of data being stored are limited to a certain number of data symbols or blocks corresponding to the number of access channels (e.g., 40 access channels to store the codeword).

Various error correction codes may be used, including Reed-Solomon (RS) codes, Bose-Chaudhuri-Hocquenghem (BCH) codes, Goppa codes, Hamming codes, and the like. More specifically, with an (n, k)×q code, a message to be stored (or communicated) may include k symbols m₀, m₁ . . . mₖ₋₁ (e.g., k=32 in the above example), each symbol encoding an element of the Galois field GF(2^{q}), e.g., polynomials of order q−1 with the addition (and subtraction) operations defined modulo 2 (bitwise XOR operations) and the multiplication (and division) operations defined modulo a suitably chosen irreducible polynomial of order q (e.g., q=8 for one-byte symbols). For example, the Reed-Solomon code may be parameterized using n different nonzero symbol labels αᵢ∈GF(2^{q}). A syndrome matrix S may be chosen to be the (n−k)×n Vandermonde matrix generated by αᵢ, namely

$$V := ( \begin{matrix}1 & … & 1 \\ {α}_{1} & … & {α}_{n} \\ ⋮ & ⋱ & ⋮ \\ {α}_{1}^{n - k - 1} & … & {α}_{n}^{n - k - 1}\end{matrix} )$$

Then given a k-symbol message, n−k parity symbols may be chosen to form up an n-symbol codeword c, which has the property that V·c=0.

After the codeword c is stored and then retrieved from the memory (or, in network communications, after the codeword is transmitted and received by a target device) the stored (received) value \tilde{c} of the codeword can be the same as the encoded codeword, \tilde{c}=c (uncorrupted value), or different from the encoded codeword, \tilde{c}≠c (corrupted value). A departure of the stored value \tilde{c} from the encoded codeword c may be quantified by calculating a syndrome V·\tilde{c}, resulting in t:=n−k syndrome values Sⱼ, which can be viewed as coefficients of a syndrome polynomial

$$S ( x ) = {\sum }_{j = 0}^{t - 1} {S}_{j + 1} {x}^{j}$$

of order t−1. Zero syndrome values, {Sⱼ}=0, indicate that the stored codeword is almost certainly the same as the encoded codeword, so that the message m₀, m₁ . . . mₖ₋₁ can be read as k first symbols of the codeword.

Nonzero values of some of the syndrome values Sⱼ indicate that one or more symbols of the codeword have been corrupted. Provided that the number of corrupted symbols is t/2 or less, the knowledge of syndrome values Sⱼ allows a decoder to identify and correct the corrupted symbols. More specifically, syndrome values Si may be used as coefficients in a key equation for an error locator polynomial Λ(x). Solution of the key equation yields the error locator polynomial Λ(x) whose roots may be used to identify locations of errors (e.g., specific corrupted symbols) and the values of those errors. The locations and values of the errors may then be used to determine an error vector, Δ, that being added to the stored codeword c allows to recover the original (uncorrupted) codeword, c=\tilde{c}+Δ.

Different ECC algorithms may be applied for protection of the same data, each having its own advantages and costs. For example, in the course of storing a 512-bit amount of data across 10 chips with 4 access channels (e.g., physical pins) each, the data may be encoded as k=64 single-byte symbols or as k=32 double-byte symbols. In the instances of k=64 data symbols, k/2=32 data symbols and t/2=8 ECC symbols may be written to the chips during a first epoch and the same number of data symbols/ECC symbols may be written during a second epoch. The total number of t=16 ECC symbols may be used to implement a (80,64)×8 code capable of correcting any t/2=8 corrupted symbols. Implementation of this (80,64)×8 code may involve a substantial number of computations (e.g., matrix multiplications). Correspondingly, for fast implementation of this code, a large number of hardware circuits may be deployed. In the instances of k=32 16-bit (double-byte) data symbols, t=8 ECC symbols may be written to the chips and used to implement a (40,32)×16 code capable of correcting t/2=4 corrupted 16-bit data symbols. Whereas a (40,32)×16 code does not have as much flexibility as a (80,64)×8 code, the two codes have the same correction ability in the instances of errors that are confined to at most 4 different channels (e.g., when 8 corrupted symbols of the (80,64)×8 code occur in pairs that use the same channels during the two epochs). Decoding a (40,32)×16 code, however, typically has a lower latency than decoding a (80,64)×8 code. Yet another possibility is to encode the 512-bit data via two separate n=40 codewords using a (40,32)×8 code for each codeword (denoted herein as (40,32)×8×2 code). The (40,32)×8×2 code is the fastest of the three codes to compute and is capable of detecting 4 one-symbol errors in each of the two codewords. In particular, (40,32)×8×2 code is capable of correcting errors that (40,32)×16 code cannot correct, but (40,32)×8×2 code has a much higher miscorrection probability, e.g., 2.1×10⁻⁵ vs. 5.0×10⁻¹⁵ for (40,32)×16 code. Miscorrection refers to a situation where a number of corrupted symbols exceeds t/2 but a code is confused into incorrectly determining that t/2 (or fewer) errors have been corrected when, in fact, the code did not detect the actual errors and/or even introduced additional errors to the data. Miscorrection is an undesirable situation that is to be avoided and detected, whenever possible, as an uncorrectable error. One possibility to reduce the probability of miscorrection is to use a restricted (40,32)×8×2 code. Even though the restricted (40,32)×8×2 code is capable of correcting up to 4 one-symbol errors in each of the two codewords, in those instances where the errors spread out to more than 4 different channels (and, therefore, would not be correctable by (40,32)×16 code), an uncorrectable error is declared. The restricted (40,32)×8×2 code achieves the low miscorrection rate (~10⁻¹⁵) of (40,32)×16 code when errors are uniformly randomized across the two codewords but lapses to the high miscorrection rate (~10⁻¹⁵) of the unrestricted (40,32)×8×2 code when errors tend to be grouped within one of the codewords.

Aspects of the present disclosure address the above noted and other challenges of the existing technology by enabling systems and techniques for correlated multi-codeword error correction that significantly reduces the likelihood of miscorrection. In some example implementation, a 512-bit block of data may be encoded using two codewords, each codeword having 40 one-byte symbols each, of which 32 symbols contain data and 8 symbols are EC symbols. A symbol

$${CW}_{j}^{( 1 )}$$

of the first codeword and a symbol

$${CW}_{j}^{( 2 )}$$

of the second codeword that are stored in the same chip and accessed through the same channel j may then be mixed using some invertible transformation, e.g., a linear transformation with some mixing matrix Mⱼ,

$$( \begin{matrix}\text{?} \\ \text{?}\end{matrix} ) = {M}_{j} ( \begin{matrix}{CW}_{j}^{( 1 )} \\ {CW}_{j}^{( 2 )}\end{matrix} ) , {M}_{j} = {( \begin{matrix}{M}_{11} & {M}_{12} \\ {M}_{21} & {M}_{22}\end{matrix} )}_{j} ,$$

before mixed symbols

$$\text{?} and \text{?}$$

may be stored in a memory chip (or communicated over a network). During codeword retrieval/decoding, the symbols

$$\text{?} and \text{?}$$

unmixed, e.g., using the inverse transformation,

$$( \begin{matrix}{CW}_{j}^{( 1 )} \\ {CW}_{j}^{( 2 )}\end{matrix} ) = {M}_{j}^{- 1} ( \begin{matrix}\text{?} \\ \text{?}\end{matrix} ) ,$$

and each of the two codewords may then be decoded according to the (40,32)×8 error correction code. Each application of the error correction code may correct up to 4 errors (in this non-limiting example). If the errors in both codewords are limited to at most four channels j, it is likely that errors have been identified correctly and that the number of errors indeed does not exceed 4 (so that no miscorrection has occurred). On the other hand, if errors in the two codewords are not in matching positions (so that corrupted symbols correspond to 5 or more different channels j), it is possible that at least one of the codewords has been miscorrected. To prevent such a situation, an uncorrectable error may thus be declared. Numerous additional implementations are disclosed herein.

The advantages of the disclosed techniques include but are not limited to reduction of occurrences of miscorrection in the course of application of error correction codes. Although the condition that correctable errors be concentrated within a limited number of channels results in declaring some correctable errors uncorrectable (e.g., when mixing causes correctable errors, whose number is less than t/2 in each codeword but located in non-overlapping channels in different codewords, to propagate across multiple channels and contaminate more than t/2 total channels), this cost may be outweighed by the reduced probability of miscorrections, which is usually a more serious condition than an uncorrectable error.

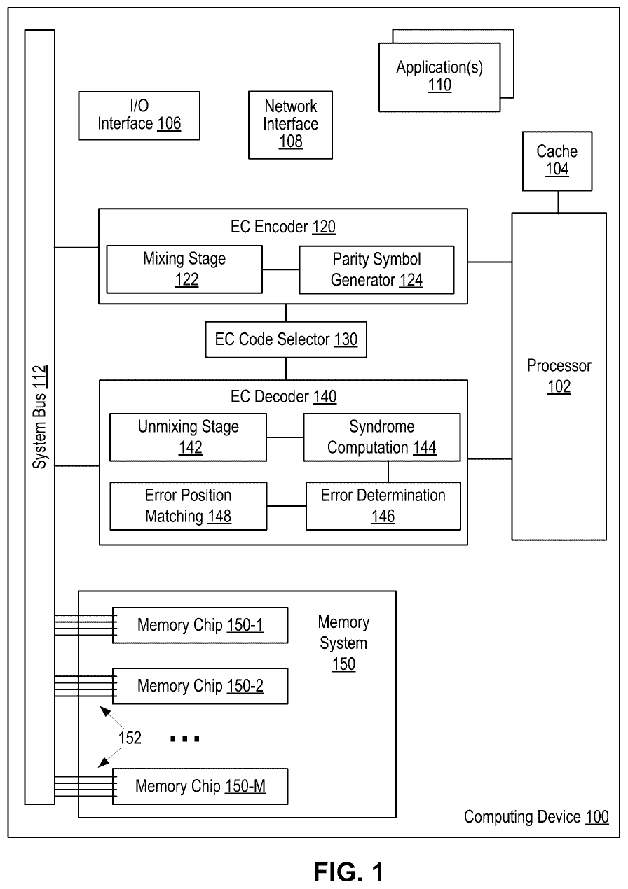

FIG. 1 is a block diagram illustrating an example computing device 100 in which implementations of the present disclosure may operate. Computing device 100 may be any desktop computer, a tablet, a smartphone, a server (local or remote), a thin/lean client device, a server, a cloud computing node, an edge device, a network switch, a gateway device, a card reader, a wireless sensor node, an Internet-of-Things (IoT) node, an embedded system dedicated to one or more specific applications, and so on. Computing device 100 may have one or more processors 102, e.g., central processing units (CPUs), graphics processing units (GPUs), field-programmable gate arrays (FPGA), application-specific integrated circuits (ASICs), and the like. “Processor” refers to a device capable of executing instructions encoding arithmetic, logical, or I/O operations. In one illustrative example, a processor may follow the von Neumann architectural model and may include one or more arithmetic logic units (ALUs), a control unit, and may further have access to a plurality of registers, or a cache 104.

Processor 102 may include one or more processor cores. In implementations, each processor core may execute instructions to run a number of hardware threads, also known as logical processors. Various logical processors (or processor cores) may be assigned to one or more processes supported by processor 102, although more than one processor core (or a logical processor) may be assigned to a single processor for parallel processing. A multi-core processor may simultaneously execute multiple instructions. A single-core processor may typically execute one instruction at a time (or process a single pipeline of instructions).

Computing device 100 may include one or more memory systems 150. The memory system 150 may refer to any volatile or non-volatile memory and may include a read-only memory (ROM), a random-access memory (RAM), electrically erasable programmable read-only memory (EEPROM), flash memory, flip-flop memory, or any other device capable of storing data. RAM may be a dynamic random-access memory (DRAM), synchronous DRAM (SDRAM), a static memory, such as static random-access memory (SRAM), and the like. In some implementations, processor(s) 102 and memory system 150 may be implemented as a single controller, e.g., as an FPGA. Memory system 150 may include multiple memory chips 150-1 . . . 150-M. In some implementations, memory chips 150-1 . . . 150-M may be accessed via memory channels 152 that allow simultaneous (parallel) write (store) and read (load) operations, e.g., simultaneous storing and/or reading of multiple data symbols.

Computing device 100 may further include an input/output (I/O) interface 106 to facilitate connection of the computing device 100 to various peripheral hardware devices (not shown in FIG. 1) such as card readers, terminals, printers, scanners, IoT devices, and the like. Computing device 100 may further include a network interface 108 to facilitate connection to a variety of networks (Internet, wireless local area networks (WLAN), personal area networks (PAN), public networks, private networks, etc.), and may include a radio front end module and other devices (amplifiers, digital-to-analog and analog-to-digital converters, dedicated logic units, etc.) to implement data transfer to/from computing device 100. Various hardware components of the computing device 100 may be connected via a system bus 112 that may include its own logic circuits, e.g., a bus interface logic unit (not shown in FIG. 1).

Computing device 100 may support one or more applications 110. Application(s) 110 supported by computing device 100 may include machine-learning application(s), graphics application(s), computational application(s), cryptographic application(s) (such as authentication, encryption, decryption, secure storage application(s), etc.), embedded application(s), external application(s), or any other types of application(s) that may be executed by computing device 100. Application(s) 110 may be instantiated on the same computing device 100, e.g., by an operating system executed by the processor 102 and residing in the memory system 150. Alternatively, the external application(s) may be instantiated by a guest operating system supported by a virtual machine monitor (hypervisor) operating on the computing device 100. In some implementations, the external application(s) may reside on a remote access client device or a remote server (not shown), with the computing device 100 providing computational support for the client device and/or the remote server.

Computing device 100 may include an error correction (EC) encoder 120 that may receive, from processor 102, a data message to be stored in memory system 150 or transmitted over network interface 108. EC encoder 120 may be configurable by an EC code selector 130 that may select a size of a symbol (e.g., 8 bits, 16 bits, and/or the like), a number of data symbols k in a codeword, a number of parity of symbols t in the codeword, a number N of codewords (e.g., two, three, four, and so on) to be mixed, a type of a code (e.g., a Reed-Solomon code, a BCH code, a Goppa code, and/or the like). Having received data from processor 102, EC encoder 120 may use a mixing stage 122 to perform channel-wise mixing of data symbols and provide the mixed symbols of the data message to a parity symbol generator 124 that may generate t=n−k parity (EC) symbols and combine parity symbols with data symbols into a codeword. In some implementations, a parity symbol generator 124 may generates a codeword encoding a 1/Nth part of the data message. This process may then be repeated for the remaining N−1 codewords of the data message. The codewords encoding the data message may be stored in memory system 150, e.g., in one or more memory chips 150-1-150-M, or transmitted over network interface 108.

Computing device 100 may include an EC decoder 140 to perform inverse operations of decoding of codewords retrieved from memory system 150 or received via network interface 108. EC decoder 140 may receive information from EC code selector 120 about the type of EC code being used, a size of a codeword, a number of codewords N that are mixed, a number of parity symbols in each codeword, and/or the like. EC decoder 140 may include an unmixing stage 142 that inverts the mixing transformation performed by mixing stage 122 of EC encoder 120. Syndrome computation 144 then calculates syndrome values for the received codewords. EC decoder 140 may include an error determination 146 that deploys a key equation solver to determine, based on the calculated syndrome values, how many errors are present in the received codewords. Error determination 146 may then identify, based on the solution of the key equation, the locations and values of the errors in the received codewords. Based on the identified locations of errors, e.g., one or more of the channels 1 . . . n used to store corresponding symbols of codewords in memory chips 150-1 . . . 150-M, error position matching 148 may determine whether the N codewords have errors in locations (channels) that exceed a threshold number (e.g., t/2) of affected locations. If the number of different error locations is no more than the threshold number, the data with corrected errors may be delivered to processor 102. If the number of different error locations exceeds the threshold number, EC decoder 140 may determine that the data has an uncorrectable error and may deliver a corresponding notification (e.g., a fault or an interrupt) to processor 102.

Any functions or components depicted as part of EC encoder 120 and/or EC decoder 140 may be implemented via dedicated hardware circuits configured to perform one or more computational operations (e.g., multiplication, addition, inversion, division, differentiation, and the like), or as software modules executed on any suitable processor (e.g., processor 102), or as any combination of dedicated hardware circuits and software modules.

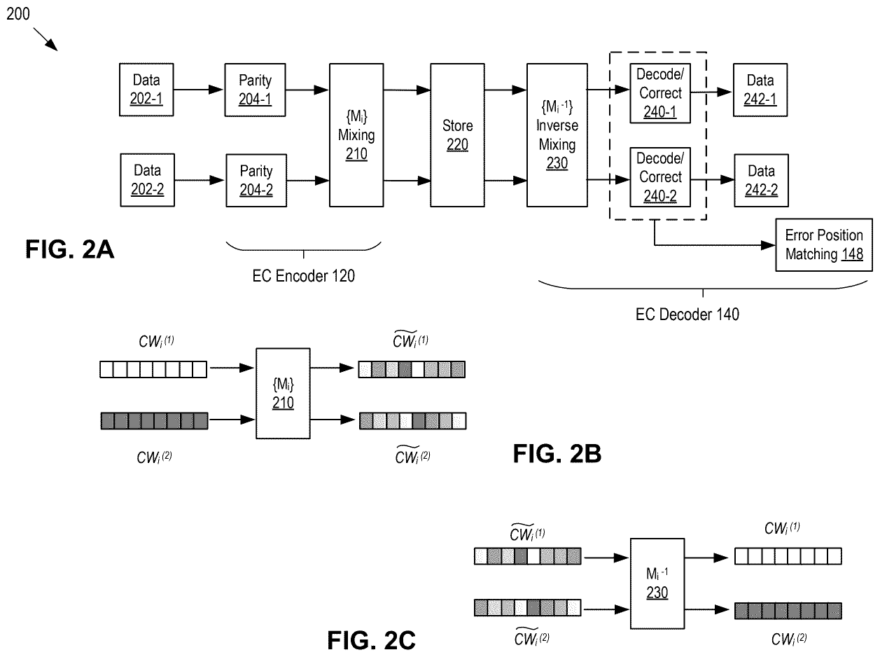

FIGS. 2A-C illustrate example operations 200 of codeword mixing for reduction of miscorrection occurrences in application of error correction codes, in accordance with some aspects of the present disclosure. In some implementations, example operations 200 may be performed by EC encoder 120 and EC decoder 130 of example computing device 100 of FIG. 1. Specifically, M memory chips 150-1 . . . 150-M may be used to store a data that includes M×L symbols, with L symbols stored per chip. Each symbol may be stored and then retrieved via a separate access channel, for speed of memory operations (writes, reads, erasures, etc.). An example memory chip may have L=4 channels, but other memory chips (e.g., with L=6, L=8, etc.) may also be used.

As illustrated in FIG. 2A, a block of data (e.g., a 512-bit block, a 256-bit block, a 1024-bit block, etc.) may include multiple portions, e.g., data 202-1 and data 202-2, which are encoded into separate codewords. For conciseness of illustration, example operations 200 use two codewords, but it should be understood that the number of used codewords N may be three, four, and/or any other number. EC encoder 120 may generate parity symbols 204-1 for data 202-1 and parity symbols 204-2 for data 202-1. More specifically, each data 202-j may include k symbols (e.g., 8-bit symbols, 12-bit symbols, 16-bit symbols, 32-bit symbols, etc.) and parity symbols 204-j may include t EC symbols for the total of n=k+t symbols

$${CW}_{j}^{( 1 )}$$

of the first codeword and the same total number of symbols

$${CW}_{j}^{( 2 )}$$

of the second codeword, where j=1 . . . n enumerates channels that are used to store and access the respective codewords. The codeword length n may be the same for each of the codewords. In some implementations, the message length k and parity length t=n−k may be the same in the different codewords, and in other implementations they may be different. Prior to storing the codewords in memory store 220 (e.g., memory chips 150-1 . . . 150-M), the codewords may undergo a mixing transformation 210, which may be an invertible transformation. In some implementations, the mixing transformation 210 may be a linear transformation that uses a 2×2 mixing matrix Mⱼ(or, more generally an N×N mixing matrix, if more than 2 codewords are being mixed):

$$( \begin{matrix}\text{?} \\ \text{?}\end{matrix} ) = {M}_{j} ( \begin{matrix}{CW}_{j}^{( 1 )} \\ {CW}_{j}^{( 2 )}\end{matrix} ) ,$$

to generate mixed symbols

$$\text{?} and \text{?}$$

In some implementations, at least some of different channels j may be associated with different mixing matrices Mⱼ. In some implementations, each channel j may be associated with a mixing matrix Mⱼ that is different from all other mixing matrices Mⱼ. In some implementations, mixing matrices Mⱼ may be selected in the following Vandermonde form

$${M}_{j} = ( \begin{matrix}1 & 1 \\ {h}_{j} & {h}_{j} + 1\end{matrix} ) ,$$

where hⱼ is a root of a quadratic equation hⱼ(hⱼ+1)=αⱼ, with αⱼ being channel-dependent labels (such as elements in of the Galois field GF(2^{q})), or as some N×N Vandermonde matrix or the inverse of another N×N Vandermonde matrix. In some implementations, mixing matrices may be selected in some alternative form, e.g.

$${M}_{j} = ( \begin{matrix}{h}_{j} + 1 & {h}_{j} \\ {h}_{j} & {h}_{j} + 1\end{matrix} ) ,$$

or in some other suitable form.

After the codewords are retrieved from memory store 220 (e.g., memory chips 150-1 . . . 150-M), a matching inverse mixing transformation 230 may be applied to each pair of symbols

$$\text{?} and \text{?}$$

(or N>2 symbols, if applicable). For example, in the instances of linear mixing transformations, the inverse mixing transformation 230 may be performed using the inverse matrix

$${M}_{j}^{- 1} ,$$

$$( \begin{matrix}{CW}_{j}^{( 1 )} \\ {CW}_{j}^{( 2 )}\end{matrix} ) = {M}_{j}^{- 1} ( \begin{matrix}\text{?} \\ \text{?}\end{matrix} ) .$$

Subsequently, each of the codewords

$$( {CW}_{1}^{( 1 )} … {CW}_{n}^{( 1 )} ) and ( {CW}_{1}^{( 2 )} … {CW}_{n}^{( 2 )} )$$

may be decoded according to the respective error correction code, e.g., (n, k)×q error correction code, and location and values of errors may be determined. For example a decode/correct stage 240-1 may decode codeword

$$( {CW}_{1}^{( 1 )} … {CW}_{n}^{( 1 )} )$$

and identify errors for decoded data 242-1 and decode/correct stage 240-2 may also decode codeword

$$( {CW}_{1}^{( 2 )} … {CW}_{n}^{( 2 )} )$$

and identify errors for decoded data 242-2. Error position matching 148 may then compare locations of errors in the two codewords. If the errors in both codewords are limited to at most t/2 channels j, it is likely that errors have been identified correctly and that the number of errors does not exceed t/2, so that no miscorrection has occurred. On the other hand, if the errors in the two codewords are not in matching positions, so that t/2+1 or more different channels j have delivered symbols determined to be incorrect, it is possible that at least one of the codewords has been miscorrected. EC decoder 140 may then declare an uncorrectable error rather than output decoded (and corrected) data 242-1 and 242-2.

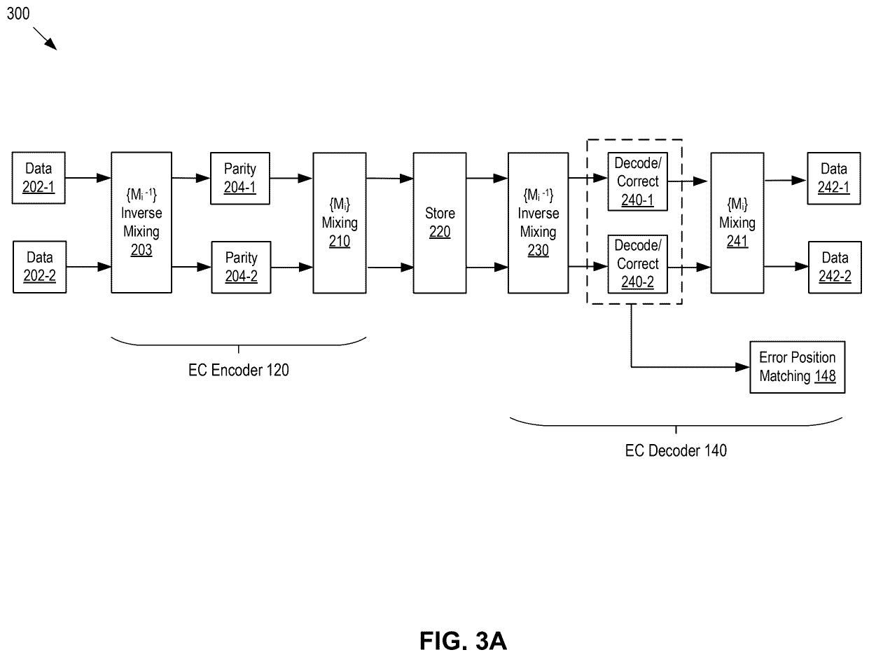

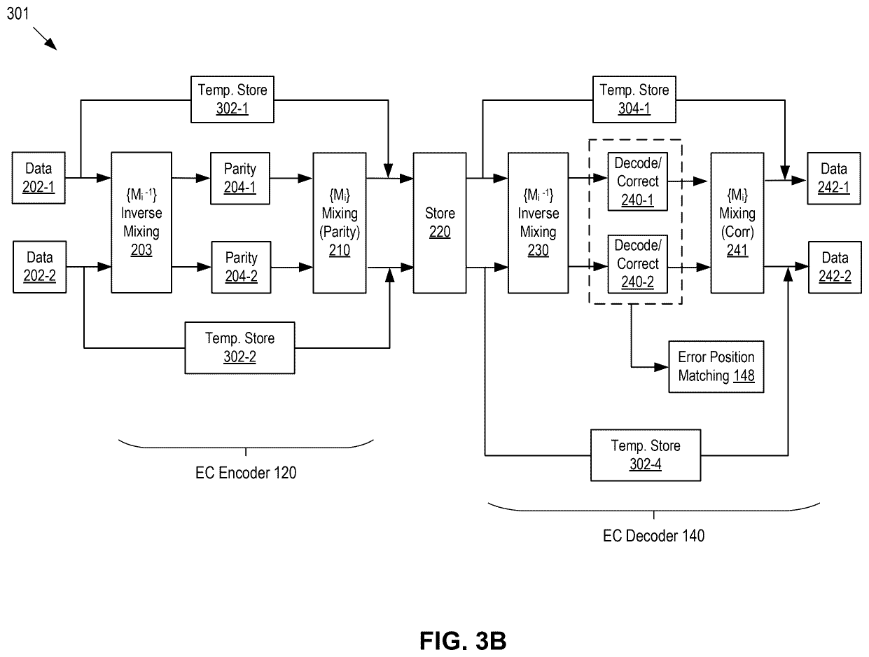

FIG. 3A illustrates example operations 300 of codeword mixing for reduction of miscorrection occurrences in application of error correction codes with systematic storage of data, in accordance with some aspects of the present disclosure. In example operations 200 of FIG. 2A, data 202-1 and 202-2 undergo the mixing transformation and is, therefore, stored in memory store 220 a non-systematic state that is different from the actual data. In example operations 300, data 202-1 and 202-2 undergo inverse mixing transformation 203 prior to computation of parity symbols 204-1 and 204-2. As a result, the mixing transformation 210 subsequently performed restores original values of the data symbols leaving only parity symbols 204-1 and 204-2 mixed. Upon retrieval of the data symbols and parity symbols from memory store 220, inverse mixing transformation 230 is performed to bring the codewords to the inverse-mixed form, which was previously used in computing parity symbols 204-1 and 204-2. Decode/correct stages 240-1 and 240-2 may then perform identification of errors and locations of the errors, which are then processed by error position matching 148, as described in conjunction with FIGS. 2A-2C, to make a determination whether an uncorrectable error is to be declared or whether the error correction has been successful. If the error correction has been deemed successful, an additional mixing stage 241 may be applied to the error-corrected codewords to restore original data 242-1 and 242-2.

FIG. 3B illustrates example operations 301 of codeword mixing with systematic storage of data and a reduced computational load, in accordance with some aspects of the present disclosure. In example operations 301, data symbols 202-1 and 202-3 may undergo inverse mixing transformation 203 and parity symbols 204-1 and 204-2 may be computed with only parity symbols 204-1 and 204-2 mixed at mixing transformation 210. Additionally, data symbols 202-1 and 202-2 may be stored, e.g., in temporary stores 302-1 and 302-2 (which may be internal registers of EC encoder 120) before being transferred to more permanent memory store 220 (e.g., memory chips 150-1 . . . 150-M). Similarly, during operations of EC decoder 140, inverse mixing transformation 230 may be applied to both the (original unmixed) data symbols 202-1 and 202-2 and parity symbols 204-1 and 204-2. Decode/correct stages 240-1 and 240-2 may then be performed and corrections determined. The mixing transformation 241 may then be applied to the determined corrections and the corrections may be applied to (original unmixed) data symbols 202-1 and 202-2 retrieved from temporary stores 304-1 and 304-2. Example operations 301 use more storage space but fewer computations compared with example operations 300 illustrated in FIG. 3A.

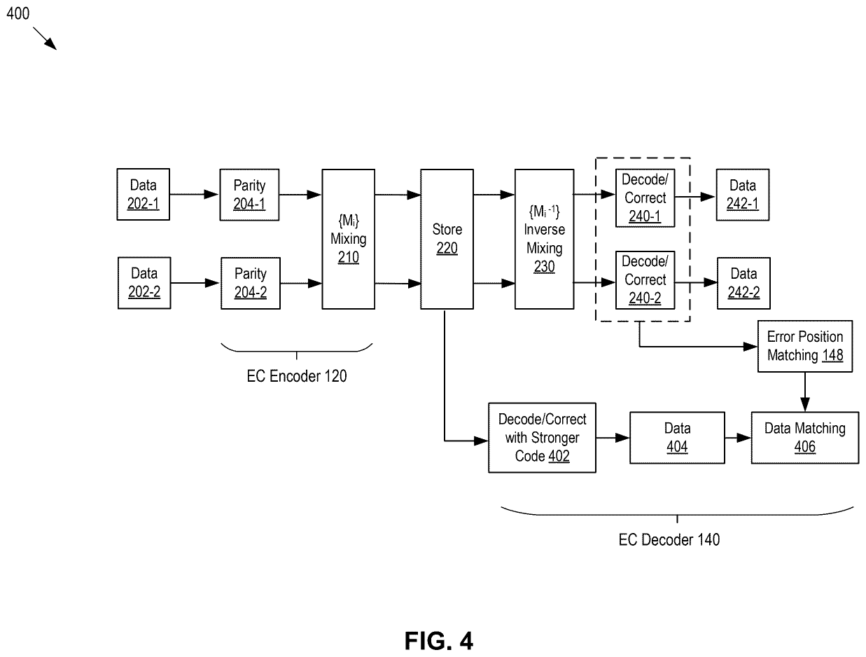

FIG. 4 illustrates example operations 400 of codeword mixing that emulates a stronger code, in accordance with some aspects of the present disclosure. More specifically, certain choices of mixing matrices Mⱼ result in a combination of mixed codewords

$$( \text{?} … \text{?} ; \text{?} … \text{?} )$$

representing a 2n-symbol codeword of a stronger code (2n, 2k)×q, e.g., the code (80,64)×8; or in general, when N codes with message lengths kᵢ are used, the stronger code may be a

$$( N \cdot n , , {\sum }_{i = 1}^{n} {k}_{i} )$$

code. The stronger code is capable of correcting a greater number of errors, for example, t=n−k errors located anywhere within 2n symbols of the combined codeword. This provides an option for EC decoder 140 to apply the stronger code to the combined mixed codeword

$$( \text{?} … \text{?} … ; \text{?} … \text{?} )$$

retrieved from memory store 220, without deploying inverse mixing transformation 230, as depicted in FIG. 4. In some implementations, decoding and error correction with the stronger code 402 is performed in addition, e.g., in parallel, to decode/correct stages 240-1 and 240-2 of the weaker code (n, k)×q×2. In such embodiments, data 404 output by the stronger code may be compared to a combination of data 242-1 and 242-2. EC decoder 140 may output the data if data matching stage 406 determines the data outputs of the two codes to be the same. If one of the codes gives a correction and the other code fails to correct the data, then EC decoder 140 may output the data corrected by the code that succeeded. In this case, EC decoder 140 may perform additional checks to reduce the probability of a miscorrection, e.g., EC decoder 140 may allow fewer errors than the code can correct, or may require the error locations to match a particular pattern. If data matching stage 406 determines data 404 to be different from the combination of data 242-1 and 242-2, EC decoder 140 may declare an uncorrectable error.

In some implementations, the faster decode/correct stages 240-1 and 240-2 of the weaker code (n, k)×q×2 may be performed first. If the errors in data 242-1 and 242-2 are deemed uncorrectable, decoding and error correction with the stronger code 402 may then be performed. In some implementations, a threshold number of errors for the stronger code may be set below the stronger code's correction capability, to ensure a lower probability of miscorrection. For example, the threshold number may be set at t−1, t−2, and so on. If the number of the errors detected and corrected is at or less than the set threshold number of errors, EC decoder 140 may output data 404. Otherwise, an uncorrectable error may be declared.

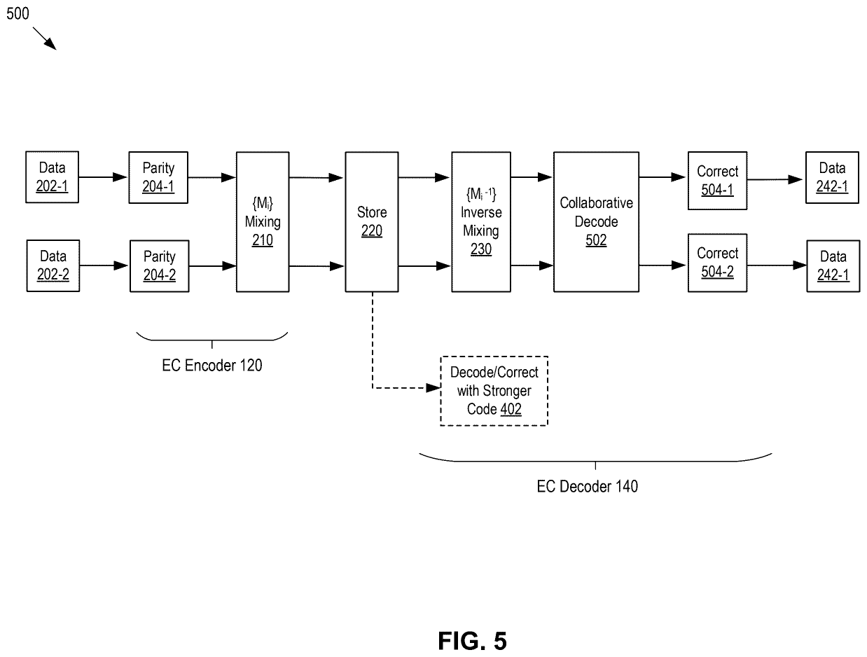

FIG. 5 illustrates example operations 500 of codeword mixing using collaborative decoding, in accordance with some aspects of the present disclosure. Collaborative decoding is a technique that attempts to explain syndromes computed for each of two (or more) codewords by assuming that errors are located within a limited number of correlated positions, e.g., within symbols associated with a certain set of channels j that is to be determined during collaborative decoding. Collaborative decoding tends to be more successful when errors are repeated in the same channel(s) for both codewords (even though the values of errors need not be the same) and tends to be less successful when errors are grouped within a single codeword. Collaborative decoding has an ability to correct some errors even in a situation where the number of errors exceeds the Singleton bound, for example when one or more of the two codewords has t/2+1 errors, t/2+2 errors, etc. (up to └2t/3┘ or, more generally, up to └Nt/(N+1)┘, if N codewords are being mixed), e.g., t/2 errors on a single chip (with t/2 channels) and additional errors associated with other channels/chips. Mixing transformation 210 of the codewords in example operations 500 spreads errors more uniformly across the same channels in the two (or more) codewords and increases the likelihood that collaborative decoding 502 is successful. Collaborative decoding 502 computes syndromes for each of two (or more) codewords and seeks to explain the computed non-zero syndrome values by assuming that errors are located within t/2, t/2+1, or more channels j and correct errors in the codewords using correct stages 504-1 and 504-2. If the search for such errors is successful, EC decoder 140 may return the corrected data 242-1 and 242-2. Otherwise, EC decoder 140 may declare an uncorrectable error. Example operations 500 may be performed with or without a stronger code decode (as illustrated schematically with the dashed box in FIG. 5).

In some implementations, to ensure that the combined mixed codeword

$$( \text{?} … \text{?} ; \text{?} … \text{?} )$$

is also a codeword of a stronger (2n, 2k)×q Reed-Solomon code, a Vandermonde mixing matrix Mᵢ may be used. To achieve this property, a suitable polynomial F(x) of degree d may be chosen, such as F(x)=x²−x with d=2, in one illustrative non-limiting example. The symbol labels αᵢ of the weaker code (n, k)×q×2 may be chosen such that F(x)−αᵢ has d different nonzero roots βᵢⱼ over the Galois field GF(2^{q}). The mixing matrix for the ith symbol position may be chosen as a d×d Vandermonde matrix generated by the roots βᵢⱼ. In this example, the stronger code is a Reed-Solomon code with symbol labels βᵢⱼ. The same (or similar) techniques may be used with a number of weaker codes that is more than two. The same (or similar) techniques may also be used in those instances where the weaker codes have the same length n and the same symbol labels αᵢ, but different message lengths k.

The weaker (n, k) Reed-Solomon codes can themselves be constructed by mixing some number of even weaker codes. In one example implementation, a stronger code may be an (80,65) Reed-Solomon code, which may be constructed by mixing weaker codes, e.g., a (40,32) and a (40,33) code. These weaker codes may have been constructed by mixing three (20,16) codes and one (20,17) code. In another example, the same (80,65) Reed-Solomon code may be constructed (and provide the same EC functionality) by mixing seven (10,8) codes and one (10,9) code. Decoding of the stronger code can be performed by applying the unmixing operation repeatedly to obtain values to be decoded with respect to any one of these weaker codes. In some implementations, attempts may be made to decode with respect to multiple different levels of mixing, either sequentially or in parallel. Decoding multiple weaker codes may be executed faster than decoding a single stronger code. Decoding with a stronger code may enable correction of a more complex pattern of errors. Decoding collaboratively using multiple weaker codes may enable correction of more total errors, if they occur in correlated positions.

Example operations 200, 300, 400, and/or 500 may be used to implement codes that accommodate additional symbol(s) of data (which may be used to store metadata or any other units of data, e.g., to simply store more data), e.g., a code (80,65)×8. Such a code, according to the Singleton bound, may be capable of correcting [(n−k)/2]=7 errors located anywhere within the 80-symbol codeword, but may also be capable of probabilistically correcting more errors provided that the errors are restricted to certain patterns. For example, a restricted pattern may include 8 errors confined to a single chip, to two chips, or any other group of 8 channels. For example, the rate of failure to correct 8 errors grouped in such patterns using a (80,65)×8 code is very small, about 1.4×10⁻¹⁷, and the rate of failure to correct 4 grouped errors using a (40,33)×4 code is about 6.0×10⁻⁸. Finding errors within such restricted patterns may be performed using error locator polynomials Λ(x) of a special simplified form. Such a form may be defined by error labels for groups of channels (e.g., chips). As another example, such error locator polynomial Λ(x) constructed for a code (40,33)×8 may be capable of identifying 4 errors (which exceeds the Singleton bound) provided that the errors are grouped on a single chip (or some other predefined group of 4 channels).

Such a restricted code may be constructed using codeword mixing techniques described above. More specifically, code (80,65)×8 may be constructed using two codes, a (40,32)×8 code and a (40,33)×8 code. Similarly, a code (40,33)×8 code may be constructed using four codes (each generating a separate codeword), e.g., three copies of a (10,8)×8 code, and one copy of a (10,9)×8 code. Each (10,8)×8 code is capable of correcting one error located anywhere and the (10,9)×8 code is capable of correcting one error provided that the location of the error is known. EC decoder 140 may decode and correct three (10,9)×8 codewords identifying an error in each of the codewords. If the errors are in the same position (channel), EC decoder 140 may use that position to correct the last codeword, if the last codeword has an error. EC decoder 140 may declare a failure if any of the codes return an uncorrectable error, if the errors are in different positions, or if only the last codeword has an error (e.g., the (10,9)×8 codeword).

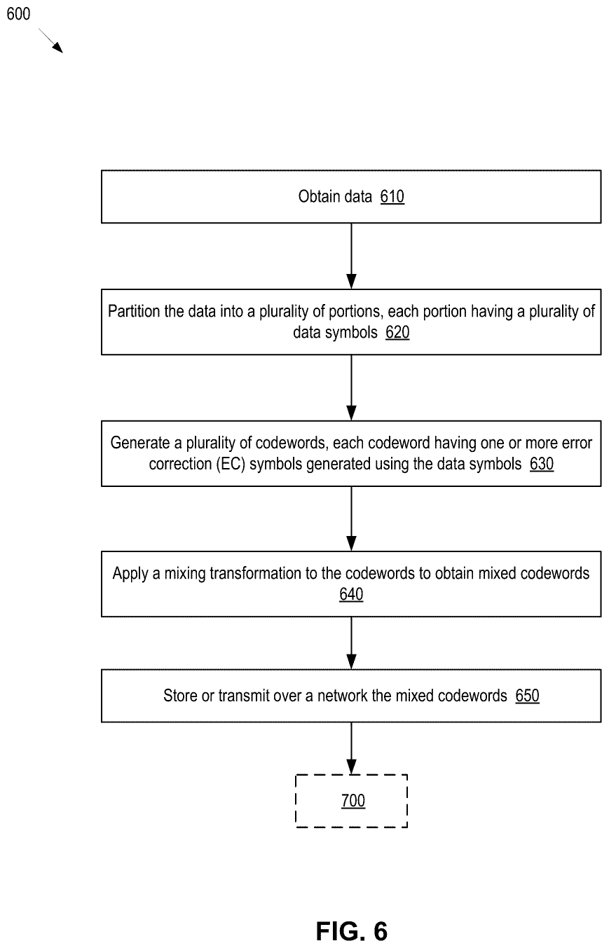

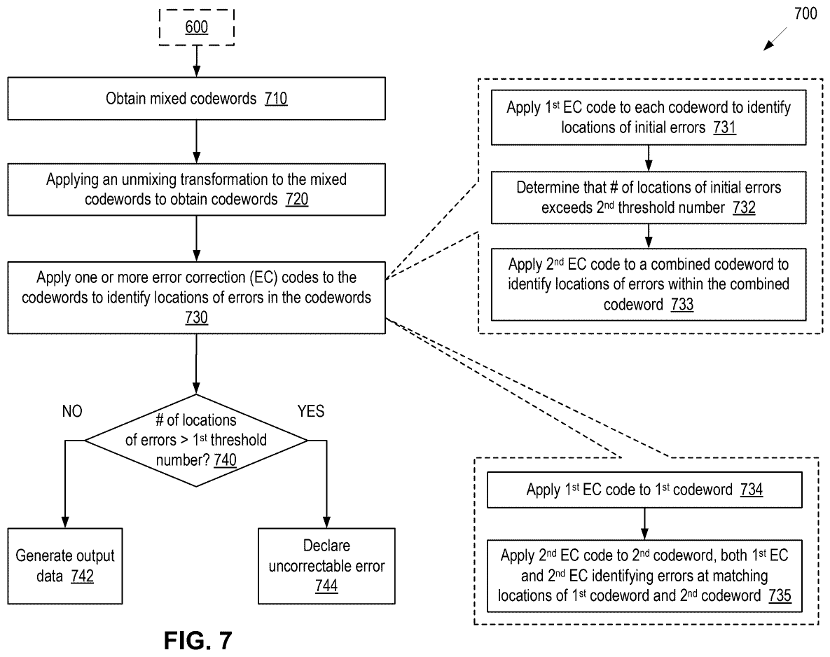

FIGS. 6-7 illustrate example methods 600 and 700 that may deploy codeword mixing for reduction of miscorrection occurrences in application of error correction codes. Methods 600 and 700 and each of their individual functions, routines, subroutines, and/or operations may be performed by an error correction engine, such as EC encoder 120 and/or EC decoder 140 in FIG. 1, any of which may be implemented via dedicated encoding/decoding circuits, or a general-purpose processor, such as processor 102 in FIG. 1. Various blocks of methods 600 and 700 may be performed in a different order compared with the order shown in FIG. 6 and FIG. 7. Some blocks may be performed concurrently with other blocks. Some blocks may be optional. Methods 600 and 700 may be implemented as part of data write and read operations or as part of a network data communication operation. In certain implementations, a single processing thread may perform any of methods 600 and 700. Alternatively, two or more processing threads may perform any of methods 600 and 700, each thread executing one or more individual functions, routines, subroutines, or operations of the methods. In an illustrative example, the processing threads implementing any of methods 600 and 700 may be synchronized (e.g., using semaphores, critical sections, and/or other thread synchronization mechanisms). Alternatively, the processing threads implementing any of methods 600 and 700 may be executed asynchronously with respect to each other. Various operations of each of methods 600 and 700 may be performed in a different order compared with the order shown in FIG. 6 and FIG. 7. Some operations of any of methods 600 and 700 may be performed concurrently with other operations. Some operations may be optional.

FIG. 6 is a flow diagram illustrating an example method 600 of codeword mixing during error correction encoding for reduction of miscorrection occurrences, in accordance with some implementations of the present disclosure. At block 610, processing units performing method 600 may obtain data. At block 620, the processing units may partition the data into a plurality of portions (e.g., data 202-1, 202-2, and the like, as depicted in FIG. 1). Each portion of the plurality of portions may include a plurality of data symbols (e.g., each data 202-j may have k symbols).

At block 630, method 600 may continue with generating a plurality of codewords. Each codeword of the plurality of codewords may be generated using a respective portion of the data and may include a plurality of data symbols and may further include one or more EC symbols (e.g., t=n−k EC symbols). In some implementations, at least two codewords of the plurality of codewords may have unequal numbers of EC symbols (e.g., a (40,32) codeword may have 8 EC symbols and a (40,33) codeword may have 7 EC symbols). In some implementations, each of the plurality of codewords may be generated using a Reed-Solomon EC code, a BCH EC code, a Goppa EC code, and/or the like.

At block 640, the processing units performing method 600 may apply a mixing transformation to the plurality of codewords to obtain a plurality of mixed codewords. In some implementations, the mixing transformation may be an invertible transformation. In some implementations, the mixing transformation may include one or more matrix multiplications. In some implementations, at least some of the matrix multiplications may be symbol-specific, e.g., symbols with matching locations j (e.g., memory access channels) in different codewords may be mixed. In some implementations, individual mixed codewords of the plurality of mixed codewords may include mixed EC symbols and unmixed data symbols (e.g. as described in conjunction with FIG. 3A and/or FIG. 3B).

At block 650, method 600 may include performing an operation using the plurality of mixed codewords. For example, the operation may include storing the plurality of mixed codewords in a memory device (e.g., in memory chips 150-1 . . . 150-M of memory system 150 in FIG. 1). The operation may also include transmitting the plurality of mixed codewords over a network.

FIG. 7 is a flow diagram illustrating an example method 700 of codeword unmixing during error correction decoding for reduction of miscorrection occurrences, in accordance with some implementations of the present disclosure. In some instances, method 700 may be performed by the same computing device that performed method 600 (e.g., if storage of data is performed locally). In some instances, method 700 may be performed by a computing device different from a computing device that performed method 600 (e.g., if data is communicated over a network). At block 710, processing units performing method 700 may obtain a plurality of mixed codewords (e.g., by retrieving the mixed codewords from a memory device, receiving the mixed codewords over a network, etc.). At block 720, the processing units may apply an unmixing transformation to the plurality of mixed codewords to obtain a plurality of (unmixed) codewords. The unmixing transformation may be an invertible transformation, e.g., an inverse of the mixing transformation referenced in conjunction with block 640 of FIG. 6. For example, the unmixing transformation may include one or more matrix multiplications. In some implementations, at least two codewords of the plurality of codewords may include unequal numbers of EC symbols (e.g., a first (40,32) codeword may have 8 EC symbols and a second (40,33) codeword may have 7 EC symbols).

At block 730, method 700 may continue with the processing units applying one or more EC codes to the plurality of (unmixed) codewords to identify locations of one or more errors in the plurality of (unmixed) codewords. The one or more EC codes may be applied in a variety of ways. In one implementation, the one or more errors may include a first set of errors located using a first EC code (e.g., (40,32)×8 code applied to a first codeword and a second codeword) and a second set of errors located using a second EC code (e.g., a (80,32)×8 code applied to a combined codeword). The locations of the one or more errors determined at block 730 may be a union of locations of the first set errors and the second set of errors. It should be understood that in some (e.g., a majority) instances of application of method 700 the first set of errors and/or the second set of errors may be empty (e.g., there may be no errors in unmixed codewords, in those instances).

Other non-limiting examples of performance of block 730 are illustrated in the callout portions of FIG. 7. More specifically, as illustrated with the top callout portion of FIG. 7, applying the one or more EC codes to the plurality of codewords may include, at block 731, applying a first EC code (e.g., (40,32)×8 code) to each codeword of the plurality of codewords to identify locations of an initial set of errors. In some implementations, the initial set of errors may be a union of errors identified for multiple codewords. At block 732, the processing units performing method 700 may determine that a number of locations of the initial set of errors exceeds a second threshold number. For example, for the (40,32)×8 code, the second threshold number may be 4. At block 733, method 700 may include applying a second (e.g., stronger) EC code to a combined codeword, which includes two or more of the plurality of codewords, to identify locations of the one or more errors within the combined codeword. For example, the second EC code may be a stronger code (e.g., (80,64)×8 code) and a first threshold for the second code may be 8 or may be set at a value that is lower than 8 (e.g., 7, 6, and so on.)

As another non-limiting example of collaborative decoding, as illustrated in the bottom callout portion of FIG. 7, applying the one or more EC codes to the plurality of codewords may include, at block 734, applying a first EC code to a first codeword of the plurality of codewords, and, at block 735, applying a second EC code to a second codeword of the plurality of codewords. In some implementations, the first EC code and the second EC code may be different instances of the same code (e.g., (40,32)×8 code). The first EC code and the second EC code may identify errors at matching locations of the first codeword and the second codeword. In some implementations, wherein a number of the matching locations does not exceed a first threshold number (e.g., collaborative decoding may be looking for errors at t/2 or fewer matching locations across both codewords). In some implementations, the first threshold number may be above a Singleton bound for at least one of the first EC code or the second EC code. For example, collaborative decoding (described in conjunction with FIG. 5) may be looking for errors at t/2+1, t/2+2, and so on, matching locations across both codewords.

At block 740, method 700 may continue with determining whether a number of the locations of the one or more errors is above a first threshold number. The first threshold number may be set using a variety of ways. For example, the first threshold number may be set at t/2 (the Singleton bound) for the respective code, below t/2 (e.g., to reduce the probability of miscorrection), or above t/2 (e.g., to correct more errors during collaborative decoding). Responsive to the determined number of locations, the processing units performing method 700 may select a processing operation from a plurality of processing operations. For example, if the number of the locations of the one or more errors is not above the first threshold number, the processing units may select, at block 742, a processing operation that generates the output data. If the number of the locations of the one or more errors is above the first threshold number, the processing units may select, at block 744, a processing operation that declares the uncorrectable error associated with the output data.

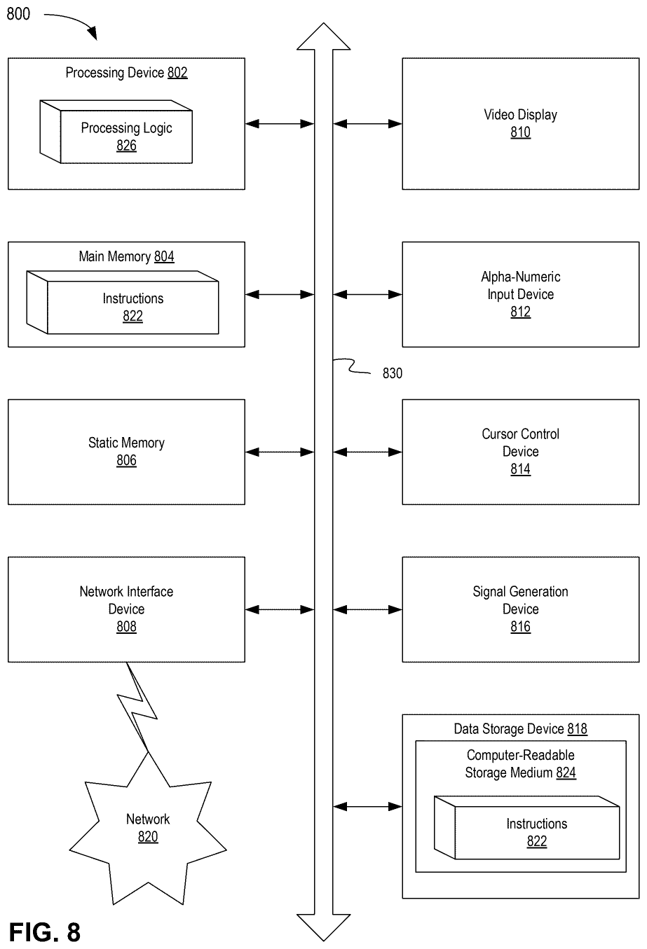

FIG. 8 depicts an example computer system 800 that can perform any one or more of the methods described herein, in accordance with some implementations of the present disclosure. The computer system may be connected (e.g., networked) to other computer systems in a LAN, an intranet, an extranet, or the Internet. The computer system may operate in the capacity of a server in a client-server network environment. The computer system may be a personal computer (PC), a tablet computer, a set-top box (STB), a Personal Digital Assistant (PDA), a mobile phone, a camera, a video camera, or any device capable of executing a set of instructions (sequential or otherwise) that specify actions to be taken by that device. Further, while only a single computer system is illustrated, the term “computer” shall also be taken to include any collection of computers that individually or jointly execute a set (or multiple sets) of instructions to perform any one or more of the methods discussed herein.

The exemplary computer system 800 includes a processing device 802, a main memory 804 (e.g., read-only memory (ROM), flash memory, dynamic random access memory (DRAM) such as synchronous DRAM (SDRAM)), a static memory 806 (e.g., flash memory, static random access memory (SRAM)), and a data storage device 818, which communicate with each other via a bus 830.

Processing device 802 (which can include processing logic 826) represents one or more general-purpose processing devices such as a microprocessor, central processing unit, or the like. More particularly, the processing device 802 may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 802 may also be one or more special-purpose processing devices such as an application specific integrated circuit (ASIC), a field programmable gate array (FPGA), a digital signal processor (DSP), network processor, or the like. The processing device 802 is configured to execute instructions 822 for implementing EC encoder 120 and EC decoder 130 of FIG. 1 and to perform the operations discussed herein (e.g., methods 600 and/or 700 of FIGS. 6-7).

The computer system 800 may further include a network interface device 808 to interface the computer system 800 to a network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), and a signal generation device 816 (e.g., a speaker). In one illustrative example, the video display unit 810, the alphanumeric input device 812, and the cursor control device 814 may be combined into a single component or device (e.g., an LCD touch screen).

The data storage device 818 may include a computer-readable storage medium 824 on which is stored the instructions 822 embodying any one or more of the methodologies or functions described herein. The instructions 822 may also reside, completely or at least partially, within the main memory 804 and/or within the processing device 802 during execution thereof by the computer system 800, the main memory 804 and the processing device 802 also constituting computer-readable media. In some implementations, the instructions 822 may further be transmitted or received over a network via the network interface device 808.

While the computer-readable storage medium 824 is shown in the illustrative examples to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing, encoding or carrying a set of instructions for execution by the machine and that cause the machine to perform any one or more of the methodologies of the present disclosure. The term “computer-readable storage medium” shall accordingly be taken to include, but not be limited to, solid-state memories, optical media, and magnetic media.

Although the operations of the methods herein are shown and described in a particular order, the order of the operations of each method may be altered so that certain operations may be performed in an inverse order or so that certain operations may be performed, at least in part, concurrently with other operations. In certain implementations, instructions or sub-operations of distinct operations may be in an intermittent and/or alternating manner.

It is to be understood that the above description is intended to be illustrative, and not restrictive. Many other implementations will be apparent to those of skill in the art upon reading and understanding the above description. The scope of the disclosure should, therefore, be determined with reference to the appended claims, along with the full scope of equivalents to which such claims are entitled.

In the above description, numerous details are set forth. It will be apparent, however, to one skilled in the art, that the aspects of the present disclosure may be practiced without these specific details. In some instances, well-known structures and devices are shown in block diagram form, rather than in detail, in order to avoid obscuring the present disclosure.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving,” “determining,” “selecting,” “storing,” “analyzing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general purpose computer selectively activated or reconfigured by a computer program stored in the computer. Such a computer program may be stored in a computer-readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear as set forth in the description. In addition, aspects of the present disclosure are not described with reference to any particular programming language. It will be appreciated that a variety of programming languages may be used to implement the teachings of the present disclosure as described herein.

Aspects of the present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read-only memory (“ROM”), random access memory (“RAM”), magnetic disk storage media, optical storage media, flash memory devices, etc.).

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” or “an implementation” or “one implementation” throughout is not intended to mean the same implementation or implementation unless described as such. Furthermore, the terms “first,” “second,” “third,” “fourth,” etc. as used herein are meant as labels to distinguish among different elements and may not necessarily have an ordinal meaning according to their numerical designation.

Whereas many alterations and modifications of the disclosure will no doubt become apparent to a person of ordinary skill in the art after having read the foregoing description, it is to be understood that any particular implementation shown and described by way of illustration is in no way intended to be considered limiting. Therefore, references to details of various implementations are not intended to limit the scope of the claims, which in themselves recite only those features regarded as the disclosure.

What is claimed is:

1. A method comprising:
obtaining data;
partitioning the data into a plurality of portions, each of the plurality of portions comprising a plurality of data symbols;
generating a plurality of codewords, wherein each of the plurality of codewords comprises one or more error correction (EC) symbols generated using a respective plurality of data symbols;
applying a mixing transformation to the plurality of codewords to obtain a plurality of mixed codewords; and
performing an operation using the plurality of mixed codewords, wherein the operation comprises at least one of:
storing the plurality of mixed codewords in a memory device, or
transmitting the plurality of mixed codewords over a network.

2. The method of claim 1, wherein the mixing transformation is an invertible transformation.

3. The method of claim 2, wherein the mixing transformation comprises one or more matrix multiplications.

4. The method of claim 3, wherein at least some of the matrix multiplications are symbol-specific.

5. The method of claim 4, wherein at least two codewords of the plurality of codewords comprise unequal numbers of EC symbols.

6. The method of claim 1, wherein individual mixed codewords of the plurality of mixed codewords comprise mixed EC symbols and unmixed data symbols.

7. The method of claim 1, wherein each of the plurality of codewords is generated using at least one of:
a Reed-Solomon EC code,
a Bose-Chaudhuri-Hocquenghem EC code, or
a Goppa EC code.

8. The method of claim 1, further comprising:
obtaining the plurality of mixed codewords;
applying an unmixing transformation to the plurality of mixed codewords to obtain a plurality of unmixed codewords;
applying one or more EC codes to the plurality of unmixed codewords to identify locations of one or more errors in the plurality of unmixed codewords;
responsive to determining whether a number of the locations of the one or more errors is above a first threshold number, selecting a processing operation from a plurality of processing operations comprising:
generating, using the plurality of unmixed codewords and the one or more errors, an output data, or
declaring an uncorrectable error associated with the output data; and
executing the selected processing operation.

9. A method comprising:
obtaining a plurality of mixed codewords;
applying an unmixing transformation to the plurality of mixed codewords to obtain a plurality of codewords;
applying one or more error correction (EC) codes to the plurality of codewords to identify locations of one or more errors in the plurality of codewords;
responsive to determining whether a number of the locations of the one or more errors is above a first threshold number, selecting a processing operation from a plurality of processing operations comprising:
generating, using the plurality of codewords and the one or more errors, an output data, or
declaring an uncorrectable error associated with the output data; and
executing the selected processing operation.

10. The method of claim 9, wherein the unmixing transformation is an invertible transformation.

11. The method of claim 9, wherein the unmixing transformation comprises one or more matrix multiplications.

12. The method of claim 9, further comprising:
responsive to determining that the number of the locations of the one or more errors is not above the first threshold number, selecting the processing operation that comprises generating the output data.

13. The method of claim 9, further comprising:
responsive to determining that the number of the locations of the one or more errors is above the first threshold number, selecting the processing operation that comprises declaring the uncorrectable error associated with the output data.

14. The method of claim 9, wherein the one or more errors comprise a first set of errors located using a first EC code of the one or more EC codes and a second set of errors located using a second EC code of the one or more EC codes, and wherein the locations of the one or more errors comprise a union of locations of the first set of errors and the second set of errors.

15. The method of claim 9, wherein applying the one or more EC codes to the plurality of codewords comprises:
applying a first EC code of the one or more EC codes to each codeword of the plurality of codewords to identify locations of an initial set of errors;
determining that a number of locations of the initial set of errors exceeds a second threshold number; and
applying a second EC code of the one or more EC codes to a combined codeword comprising two or more of the plurality of codewords to identify locations of the one or more errors within the combined codeword.

16. The method of claim 9, wherein applying the one or more EC codes to the plurality of codewords to identify locations of one or more errors in the plurality of codewords comprises:
applying a first EC code of the one or more EC codes to a first codeword of the plurality of codewords; and
applying a second EC code of the one or more EC codes to a second codeword of the plurality of codewords, wherein the first EC code and the second EC code identify errors at matching locations of the first codeword and the second codeword, wherein a number of the matching locations does not exceed the first threshold number.

17. The method of claim 16, wherein the first threshold number is above a Singleton bound for at least one of the first EC code or the second EC code.

18. The method of claim 9, wherein applying the one or more EC codes to the plurality of codewords comprises:
applying a first EC code of the one or more EC codes to the plurality of codewords;
determining that the first EC code has failed to correct the one or more errors in the plurality of codewords;
applying a second EC code of the one or more EC codes to the plurality of codewords to identify locations of the one or more errors;
selecting the processing operation that comprises generating the output data.

19. The method of claim 9, wherein at least two codewords of the plurality of codewords comprise unequal numbers of EC symbols.

20. The method of claim 9, wherein obtaining the plurality of mixed codewords comprises:
obtaining an input data;
partitioning the input data into a plurality of portions, each of the plurality of portions comprising a plurality of data symbols;
generating a plurality of codewords, wherein each of the plurality of codewords comprises one or more EC symbols generated using a respective plurality of data symbols;
applying a mixing transformation to the plurality of codewords to obtain a plurality of mixed codewords.

21. A system comprising:
a memory system; and
one or more processing units operatively coupled to the memory system, the one or more processing units to:
obtain a plurality of mixed codewords;
apply an unmixing transformation to the plurality of mixed codewords to obtain a plurality of codewords;
apply one or more error correction (EC) codes to the plurality of codewords to identify locations of one or more errors in the plurality of codewords;
responsive to determining whether a number of the locations of the one or more errors is above a first threshold number, select a processing operation from a plurality of processing operations comprising:
generating, using the plurality of unmixed codewords and the one or more errors, an output data, or
declaring an uncorrectable error associated with the output data; and
execute the selected processing operation.
